(19) United States
(12) Patent Application Publication
(10) Pub. No.: US 2026/0204332 A1
(43) Pub. Date: Jul. 16, 2026

(54) PEC-BASED DIE READ LEVEL READ OFFSET

(71) Applicant: Micron Technology, Inc., Boise, ID (US)

(72) Inventors: Murong Lang, San Jose, CA (US); Li-Te Chang, San Jose, CA (US); Zhenming Zhou, San Jose, CA (US)

(21) Appl. No.: 19/020,698

(22) Filed: Jan. 14, 2025

(51) Int. Cl. G11C 16/34; G11C 29/56

(52) U.S. Cl. CPC G11C 16/3495; G11C 16/3404; G11C 29/56016

(57) ABSTRACT

A system and method for reading data from a memory device are provided. The system and method determine a center of valley (CoV) shift for an individual memory die and generate a read offset by program-erase count (PEC) (ROBP) lookup table individually associated with the individual memory die based on the determined CoV shift, the ROBP lookup table including read level offset values for different word line groups and PEC counts. The system and method apply the ROBP lookup table to adjust read levels for the individual memory die during memory operations to compensate for threshold voltage degradation.

### TECHNICAL FIELD

This disclosure relates generally to memory sub-systems and, more specifically, to providing adaptive media management for memory components, such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 is a block diagram of an example ROBP table, in accordance with some examples.

FIG. 3 illustrates a diagram of operations performed using the media operations manager, in accordance with some examples.

FIG. 4 is a block diagram of an example computer system, in accordance with some examples.

### DETAILED DESCRIPTION

The present disclosure configures a memory device and processing device to perform die-specific read level offset adjustments based on center of valley (CoV) shift measurements. Specifically, when reading data from the memory device, the processing device determines CoV shifts for individual memory dies and generates customized read offset by program-erase count (ROBP) lookup tables for each memory die. The ROBP lookup tables contain read level offset values that vary based on word line (WL) groups (WLG) and program-erase cycle counts (PEC) to compensate for threshold voltage degradation. The processing device can determine CoV shifts during wafer-level testing using sacrificial blocks and/or through system background scans at predetermined PEC intervals (e.g., 3K, 7K, 10K cycles). For each memory die, the processing device applies its unique ROBP lookup table to adjust read levels during memory operations, which helps manage die-to-die variations of 20-60 millivolts in level 7 shifts and improves trigger rate margins by 2-4 dB. This die-specific selection of read level offsets, based on measured CoV shifts helps improve yield by enabling failing trigger rate dies to pass screening and enhances overall memory system performance, particularly for high PEC conditions.

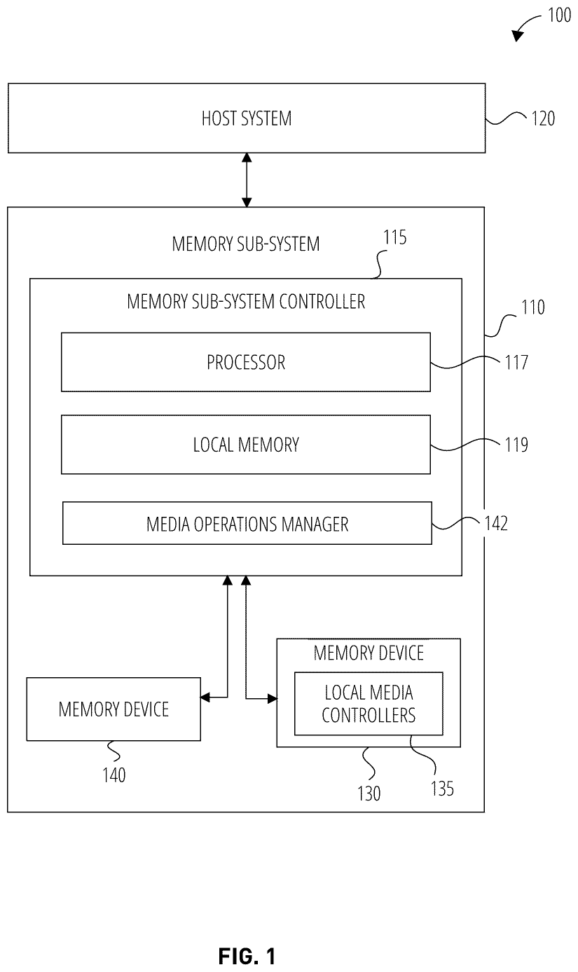

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

Memory devices use ROBP lookup tables to compensate for threshold voltage degradation that occurs after different ranges of program-erase cycling. These ROBP tables contain important read level offset values that may need to be applied at different PEC counts to maintain proper read operations as the memory cells degrade over time. For tri-level cell (TLC) memory devices with seven threshold voltage levels, issues are generally observed in the read window budget at the E12 and E13 edges between L6 and L7 levels, where precise read level adjustments are needed for maintaining reliable operation.

Conventional systems generate a single ROBP lookup table that is applied across all memory dies in the memory sub-system. This ROBP table is typically generated by selecting minimum edge margins across all memory dies, WLs, and test conditions, which results in the ROBP table being optimized for worst-case scenarios. The current ROBP table generation methods can be particularly problematic because edge margins often come from different memory dies under different test conditions, leading to overly pessimistic offset values. This is usually evident when comparing WLG0 to WLG5, where E12/E13 variations increase after certain numbers of program-erase cycles.

This conventional approach creates significant inefficiencies because the ROBP table becomes sub-optimal for the majority of memory dies that exhibit median behavior. For example, in level 7 read operations, the conventional method can result in offset values that are up to 70 millivolts different from what would be optimal for median-performing memory dies. This mismatch leads to higher trigger rates (involving error handling operations to correct data being read) performed for median memory dies, which negatively impacts overall system performance. This is so because the majority of memory dies in a memory sub-system may exhibit median behavior rather than worst-case characteristics. The impact is particularly severe for WLG0, where ROBP offset values may be too large for median memory dies, directly affecting the read window budget between threshold voltage distributions. The traditional approach also fails to account for significant die-to-die variations in CoV shifts, which can range from 20 to 60 millivolts for level 7 operations. By using a single ROBP lookup table across all memory dies, conventional systems cannot properly compensate for these variations, resulting in suboptimal read performance and potential yield issues as some memory dies may fail trigger rate screening due to the imprecise offset values being applied.

The present disclosure addresses these technical challenges by providing a memory sub-system controller (memory controller) that can determine specific conditions of the memory device and select appropriate read level voltage offsets accordingly. Specifically, when reading a portion that corresponds to a PB, the memory controller can determine conditions such as slow charge loss (SCL), PEC indicating beginning of life (BOL), middle of life (MOL), or end of life (EOL), and/or temperature ranges. Based on these conditions, the memory controller can select appropriate read level offsets from offset tables-using the inner WL offset table for inner WLs and applying a modified boundary WL offset combined with the inner WL offset for boundary WLs. Rather than using static offsets that become inadequate at different life stages, the memory controller dynamically selects read level offset adjustments based on the current operating conditions.

The present disclosure addresses these technical challenges by providing a memory device and processing device that can determine and compensate for die-specific variations in read level characteristics. Specifically, the processing device determines CoV shifts for individual memory dies and generates customized ROBP lookup tables for each memory die. The processing device can determine these CoV shifts through wafer-level testing using sacrificial blocks and/or through system background scans at predetermined PEC intervals (e.g., 3K, 7K, 10K cycles). Based on these measurements, the processing device generates die-specific ROBP tables that account for variations in threshold voltage distributions, particularly the E12/E13 edges between L6 and L7 levels that show increased variation after certain program-erase cycles and data retention. Rather than using a single static ROBP table that becomes sub-optimal for median-performing memory dies, the processing device applies customized read level offset adjustments for each memory die based on its measured characteristics. This memory die-specific approach helps manage variations of 20-60 millivolts in level 7 shifts, improves trigger rate margins by 2-4 dB, and enables failing trigger rate dies to pass screening, particularly under high PEC conditions.

In some examples, a memory sub-system can include a memory device and a processing device that are operatively coupled together. The processing device can be configured to perform operations that determine a CoV shift for an individual memory die, generate a customized read offset by program-erase count lookup table for that die, and apply the table to adjust read levels during memory operations. In some implementations, the processing device can measure read level variations during system background scan operations at predetermined program-erase cycle intervals, such as at 3,000 cycles, 7,000 cycles, or 10,000 cycles.

The lookup table can contain read level offset values for different WLGs and PECs. In some cases, the table includes offset values for at least fifteen word line groups and at least seven read levels. The table may contain values for different program-erase cycle ranges, such as 0-999 cycles, 1000-2999 cycles, 3000-6999 cycles, and cycles above 7000. In some implementations, determining the center of valley shift can involve measuring valley shifts between adjacent threshold voltage distributions. The processing device can access a lookup table that was generated during manufacture of the memory die through testing operations. These testing operations can involve selecting a sacrificial block during wafer-level probe testing, applying fast cycling to that block, and measuring slow charge loss behavior.

The CoV shift can be determined based on the measured charge loss behavior to generate the lookup table before the memory die is used in system operations. In some cases, these testing operations are repeated for each memory die during wafer-level probe testing, with threshold voltage distributions measured for multiple read levels in the sacrificial block of each die. The read level offset values can then be calculated based on these measurements. The processing device can screen memory dies using the generated lookup tables during probe testing. Memory dies that fail trigger rate screening can potentially pass when their individual lookup tables are applied.

In some examples, determining the center of valley shift can involve measuring bit error counts for level 7 or measuring a valley center for level 7 and comparing it to an original read level. The ROBP lookup table can be updated based on these measurements. The memory device can be implemented as a TLC NAND flash memory device and/or as a three-dimensional (3D) NAND device.

The memory sub-system can also be implemented through instructions stored on non-transitory machine-readable storage media that, when executed, cause a processing device to perform the operations. The operations can also be implemented as a method that determines center of valley shifts for individual dies and generates customized lookup tables to adjust read levels during memory operations.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

In some examples, the memory device 130, including one or more portions (e.g., one or more WLs, one or more WLGs, one or more blocks, one or more memory dies, and/or one or more pages) or group of memory components including the memory device 130, can be associated with a first reliability (capability) grade, value, measure, or lifetime PEC. The terms “reliability grade,” “value” and “measure” are used interchangeably throughout and can have the same meaning. The memory device 140 (e.g., one or more WLs, one or more WLGs, one or more blocks, one or more memory dies, and/or one or more pages) or group of memory components, including the memory device 140, can be associated with a second reliability (capability) grade, value, measure, or lifetime PEC. In some examples, each memory component (memory device 130 and memory device 140) can store respective configuration data that specifies the respective reliability grade and lifetime PEC, and current PEC and/or other conditions discussed below. In some examples, a memory or register can be associated with all of the memory components (memory device 130 and memory device 140) and can store a table that maps different groups, portions, bins or sets of the memory device 130 and memory device 140 to respective reliability grades, conditions, lifetime PEC values, and/or current PEC values.

In some examples, a memory or register can be associated with all of the memory components (memory device 130 and memory device 140) and can store a table or map that maps different WL, WLGs, SBs, memory dies, and/or portions of the memory components to reliability values that transgress a threshold and/or conditions. Namely, the memory or register can store a map that lists each WL, WLG, and/or SB that has been determined during manufacture to be defective (e.g., have a reliability value that fails to transgress a reliability threshold). In some cases, the table or map can be generated based on a distribution of errors or defects associated with a certain wafer, die sort, lot, or batch. A determination can be made that the memory sub-system 110 is part of a particular wafer, die sort, lot or batch and can then be loaded with the configuration data that includes the table or map associated with another memory sub-system 110 that is part of the same wafer, die sort, lot, or batch. In some cases, the list of portions that are in the table are referred to as mandatory WLs or mandatory portions (e.g., predetermined portions of the set of memory components). These mandatory portions can be included in an extrinsic defect scan operation (e.g., a read disturb scan operation) to condition performing refresh operations if the RBER of the data read from the portions transgresses a maximum or predefined RBER threshold.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), an Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells, such as multi-level cells (MLCs), tri-level cells (TLCs), quad-level cells (QLCs), and penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as an SLC block, a block including MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing GC operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., LBA, namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

In some examples, the media operations manager 142 performs several operations to enable die-specific read level adjustments. The media operations manager 142 determines CoV shifts for individual memory dies (e.g., memory device 130 and/or memory device 140) and generates customized ROBP lookup tables based on these measurements for each memory device 130 and memory device 140. For example, if the memory sub-system 110 includes two memory dies, the media operations manager 142 can store and manage two separate ROBP tables, one for each of the two memory dies. The management of these ROBP tables is discussed below as updating the values stored in the ROBP tables over time as the PEC increases and reaches certain ranges. These ROBP tables can be applied to adjust read levels of data read from the associated memory dies during memory operations to compensate for threshold voltage degradation.

During manufacture, the media operations manager 142 (or some other internal or external component, such as a processor of a probe that implements some of the functionality of the media operations manager 142) can perform testing operations using sacrificial blocks during wafer-level probe testing. For each memory die, the media operations manager 142 can select a sacrificial block and can apply fast cycling to that block. A sacrificial block refers to a designated block within a memory die that is specifically selected during wafer-level probe testing to characterize the memory die's behavior. During manufacture, this sacrificial block is intentionally subjected to accelerated wear through fast cycling operations to measure SCL behavior and determine CoV shifts for the individual memory die. The sacrificial block can be used to generate the initial ROBP lookup table values unique and specific to that individual memory die before the individual memory die enters normal system operations. This allows the processing device to establish baseline read level offset values that are customized for that specific die's characteristics. By applying intensive testing operations to the sacrificial block rather than the entire die, manufacturers can efficiently determine die-specific variations while preserving the majority of the die's storage capacity for normal use. Due to the accelerated fast cycling applied during testing, the sacrificial block experiences significantly more program-erase cycles than would be typical during normal operation, effectively consuming its program-erase cycle budget. This intensive testing causes threshold voltage degradation and charge loss behavior that renders the block unsuitable for normal data storage operations, hence the term “sacrificial” as the block is sacrificed during testing to characterize the behavior of the entire memory die.

The media operations manager 142 can measure the SCL behavior. The media operations manager 142 can measure threshold voltage distributions for multiple read levels in the sacrificial block and calculate initial read level offset values based on these measurements. This includes measuring valley shifts between adjacent threshold voltage distributions and determining center of valley shifts based on the measured SCL behavior to generate the initial ROBP lookup table before the memory die is used in system operations.

After implementation in the memory sub-system 110, the media operations manager 142 can update the ROBP lookup table values through in-field measurements. The media operations manager 142 can conduct system background scans at predetermined program-erase cycle intervals (e.g., 3K, 7K, 10K cycles) to measure read level variations. During these scans, the media operations manager 142 can measure bit error counts for level 7 (and/or any other suitable level) and can measure valley centers, comparing them to original read levels to determine if adjustments are needed. Based on these real-time measurements, the media operations manager 142 updates the ROBP lookup table to maintain optimal read level offsets as the device ages and experiences more program-erase cycles.

In managing lookup ROBP tables, the media operations manager 142 can calculate and updates read level offset values based on measured distributions and shifts. The media operations manager 142 can maintain comprehensive tables containing offset values for different WLGs and program-erase cycle ranges. These can cover at least fifteen word line groups and seven read levels. The ROBP tables include specific offset values for various cycle ranges, from early-life cycles through extended use.

The media operations manager 142 can also perform screening operations during probe testing. The media operations manager 142 can screen memory dies using the generated ROBP lookup tables and identifies dies that fail trigger rate requirements. By applying customized ROBP tables, the media operations manager 142 can enable some failing trigger rate dies to pass screening, effectively managing die-to-die variations of 20-60 millivolts in level 7 shifts. These operations collectively improve trigger rate margins and enhance memory system performance, particularly under high program-erase cycle conditions.

Any discussion with respect to the memory device 130 can similarly be applied to the memory device 140. Any function pertaining to the local media controllers 135 can, in some cases, be performed by the device) memory sub-system controller 115 and/or by an external controller, such as by host system 120.

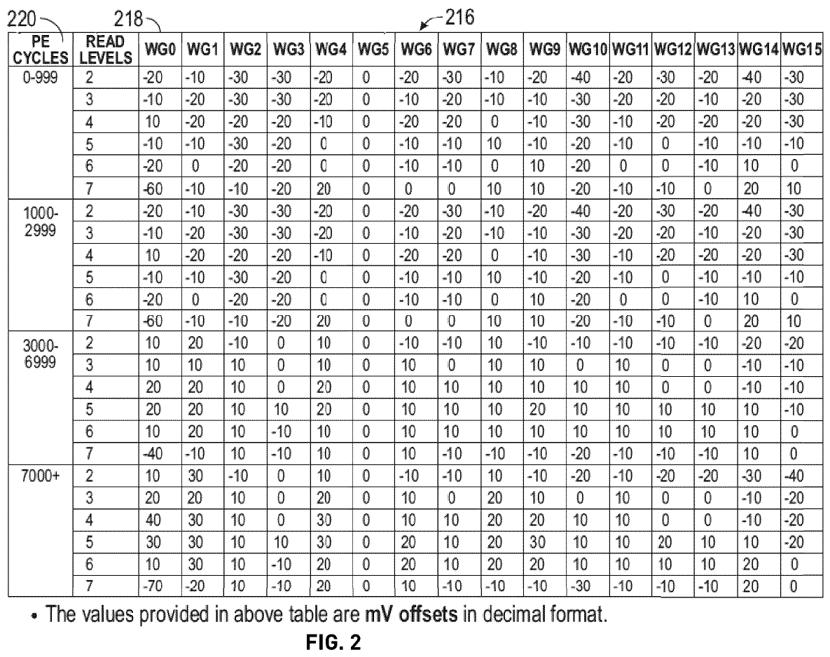

FIG. 2 is a block diagram of an example ROBP table 216, in accordance with some examples. Specifically, the ROBP table 216 can store read level offset values for an individual memory die and can be manufactured specifically for that individual memory die, such as using one or more sacrificial blocks. The table can be organized as a matrix containing offset values that vary based on PECs 220 and wordline groups 218. For each combination of PE cycles and WLG, the table stores specific millivolt offset values that can be used to adjust read levels during memory operations.

The initial values in the ROBP table 216 can be determined during the manufacturing process through wafer-level probe testing. During this phase, the processing device of a test probe selects a sacrificial block from the memory die and subjects it to fast cycling to measure SCL behavior. The processing device then analyzes threshold voltage distributions and CoV shifts from these measurements to establish the initial offset values that populate the ROBP table 216.

During wafer-level probe testing, the processing device performs a systematic characterization of each memory die using dedicated sacrificial blocks. For each memory die, the device selects a sacrificial block and subjects it to accelerated wear through fast cycling operations. This intensive testing process measures SCL behavior and determines CoV shifts that are unique to that specific memory die. The testing operations include measuring threshold voltage distributions for multiple read levels in the sacrificial block and calculating initial read level offset values based on these measurements. The testing process generates customized ROBP lookup tables before each memory die enters system operations. These tables are created by analyzing the measured SCL behavior and calculating appropriate offset values for different word line groups and program-erase cycle ranges. The process enables failing trigger rate dies to pass screening by applying die-specific offset values that account for variations of 20-60 millivolts in level 7 shifts.

The table is structured to accommodate different phases of the memory die's lifecycle, with distinct sections for PE cycle ranges from early use (0-999 cycles) through extended operation (7000+ cycles). Within each PE cycle range, the ROBP table 216 maintains specific offset values across multiple word line groups (WLG0 through WLG15) and read levels (1-7). These values are important for maintaining optimal read performance as the memory cells experience wear from repeated program-erase operations. The ROBP table 216 can be stored as part of the configuration information in the local memory 119 of the memory sub-system 110. Assuming multiple memory dies are included in the memory sub-system 110, a separate ROBP table 216 can be generated and stored in in the local memory 119 for each memory die. In some cases, the ROBP table 216 is stored in the configuration register of that specific memory die (e.g., memory device 130) and is used by the local media controllers 135 of the specific memory die.

The memory sub-system 110 can maintain separate ROBP lookup tables for different memory dies within the same system. Each memory device in the sub-system can include local media controllers that operate in conjunction with the memory sub-system controller to execute operations on their respective memory cells. The system can store multiple ROBP tables 216, each containing unique offset values tailored to the specific characteristics of individual dies as measured during manufacture and updated during operation. For example, one memory die might need larger offset adjustments for WLG0 compared to another die in the same memory sub-system 110, based on their individual center of valley shift measurements. The memory sub-system 110 maintains these distinct tables and applies the appropriate offsets during read operations for each specific memory die, enabling optimized performance across all memory components in the memory sub-system 110.

Once the memory die is in operation, the ROBP table 216 values can be dynamically updated through two primary mechanisms. First, the processing device (e.g., the memory sub-system controller 115 and/or the local media controllers 135) conducts system background scans at predetermined program-erase cycle intervals, such as at 3,000, 7,000, and 10,000 cycles of the entire memory device 130 or certain WLGs or blocks. During these scans, the processing device measures current read level variations and updates the corresponding offset values in the ROBP table 216. Second, the processing device performs real-time measurements of bit error counts and valley centers, particularly for level 7 operations, comparing these measurements against original read levels to determine if adjustments to the offset values are needed.

The offset values in the ROBP table 216 show significant variation across different word line groups and PE cycle ranges, reflecting the unique characteristics of the memory die. For example, WLG0 typically may need more substantial offset adjustments compared to WLG5, particularly for level 7 operations. This variation accounts for the increased E12/E13 variations that develop after program-erase cycling and data retention periods.

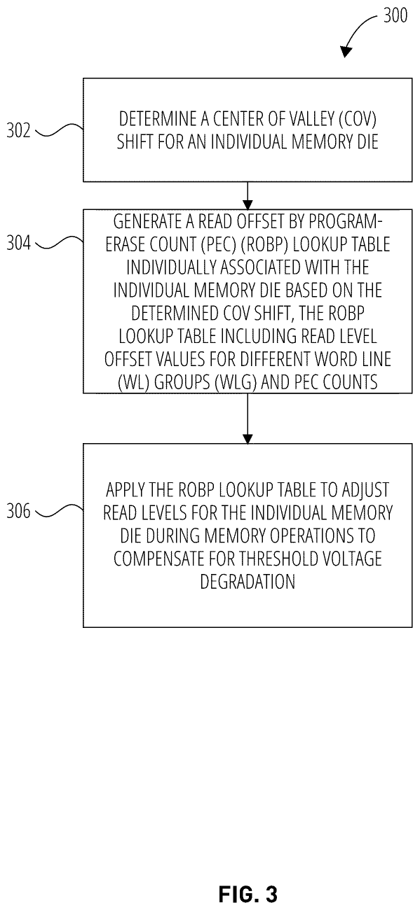

FIG. 3 illustrates a diagram 300 of operations performed using the media operations manager 142, in accordance with some examples. The method or process of diagram 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 300 is performed by the memory sub-system controller 115, local media controllers 135, and/or subcomponents of the memory sub-system controller 115 and/or local media controllers 135 of FIG. 1. In these examples, the method or process of diagram 300 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example. Other process flows are possible.

Referring now to FIG. 3, the method begins at operation 302 with the media operations manager 142 determining a CoV shift for an individual memory die. At operation 304, the media operations manager 142 generates a read offset by ROBP lookup table individually associated with the individual memory die based on the determined CoV shift, the ROBP lookup table including read level offset values for different WLGs and PEC counts. At operation 306, the media operations manager 142 applies the ROBP lookup table to adjust read levels for the individual memory die during memory operations to compensate for threshold voltage degradation.

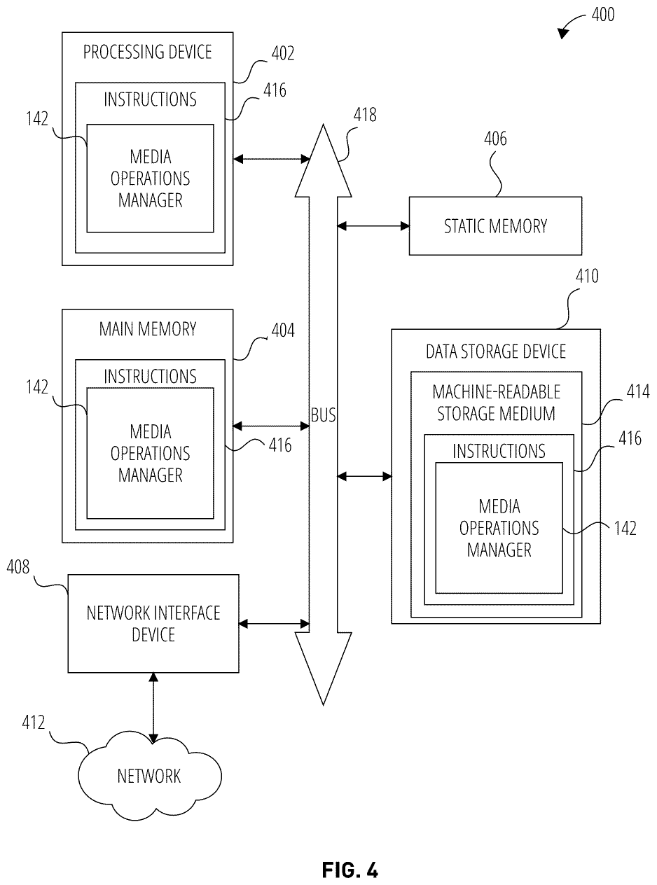

FIG. 4 illustrates an example machine in the form of a computer system 400 within which a set of instructions can be executed for causing the machine to perform any one or more of the methodologies discussed herein. In some examples, the computer system 400 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 400 includes a processing device 402, a main memory 404 (e.g., ROM, flash memory, DRAM such as SDRAM or Rambus DRAM (RDRAM), etc.), a static memory 406 (e.g., flash memory, static random access memory (SRAM), etc.), and a data storage device 410, which communicate with each other via a bus 418.

The processing device 402 represents one or more general-purpose processing devices such as a microprocessor, a central processing unit, or the like. More particularly, the processing device 402 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 402 can also be one or more special-purpose processing devices such as an application-specific integrated circuit (ASIC), a field programmable gate array (FPGA), a digital signal processor (DSP), a network processor, or the like. The processing device 402 is configured to execute instructions 416 for performing the operations and steps discussed herein. The computer system 400 can further include a network interface device 408 to communicate over a network 412.

The data storage device 410 can include a machine-readable storage medium 414 (also known as a computer-readable medium) on which is stored one or more sets of instructions 416 or software embodying any one or more of the methodologies or functions described herein. The instructions 416 can also reside, completely or at least partially, within the main memory 404 and/or within the processing device 402 during execution thereof by the computer system 400, the main memory 404 and the processing device 402 also constituting machine-readable storage media. The machine-readable storage medium 414, data storage device 410, and/or main memory 404 can correspond to the memory sub-system 110 of FIG. 1.

In one example, the instructions 416 include instructions to implement functionality corresponding to providing block failure protection for a zone memory sub-system as described herein (e.g., the REH component 113 of FIG. 1). While the machine-readable storage medium 414 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.
Example 1: A system comprising: a memory device; and a processing device, operatively coupled to the memory device, configured to perform operations comprising: determining a center of valley (CoV) shift for an individual memory die; generating a read offset by program-erase count (PEC) (ROBP) lookup table individually associated with the individual memory die based on the determined CoV shift, the ROBP lookup table including read level offset values for different word line (WL) groups (WLG) and PEC counts; and applying the ROBP lookup table to adjust read levels for the individual memory die during memory operations to compensate for threshold voltage degradation.
Example 2. The system of Example 1, the operations comprising: measuring read level variations during system background scan operations at predetermined PEC intervals.
Example 3. The operations of Example 2, wherein the predetermined PEC intervals comprise at least one of 3,000 cycles, 7,000 cycles, or 10,000 cycles.
Example 4. The system of any one of Examples 1-3, wherein the ROBP lookup table comprises read level offset values for at least fifteen word line groups.
Example 5. The system of Example 4, wherein the ROBP lookup table comprises read level offset values for at least seven read levels.
Example 6. The system of Example 5, wherein the ROBP lookup table comprises read level offset values for at least four different PEC ranges.
Example 7. The system of Example 6, wherein the PEC ranges comprise 0-999 cycles, 1000-2999 cycles, 3000-6999 cycles, and 7000+cycles.
Example 8. The system of any one of Examples 1-7, the operations comprising: measuring valley shifts between adjacent threshold voltage distributions of a specific read level.
Example 9. The system of any one of Examples 1-8, the operations comprising: accessing the ROBP table generated during manufacture of the individual memory die, the ROBP table generated during manufacture by performing testing operations comprising: selecting a sacrificial block during wafer-level probe testing of the individual memory die; applying fast cycling to the sacrificial block; and measuring slow charge loss (SCL) behavior of the sacrificial block.
Example 10. The system of Example 9, the testing operations comprising: determining the CoV shift based on the measured SCL behavior to generate the ROBP lookup table before the individual memory die is used in system operations.
Example 11. The system of Example 10, the testing operations comprising: repeating the testing operations for each memory die during the wafer-level probe testing; measuring threshold voltage distributions for multiple read levels in the sacrificial block of each respective memory die; and calculating read level offset values based on the measured threshold voltage distributions.
Example 12. The system of Example 11, the testing operations comprising: screening the individual memory die using the generated ROBP lookup table during probe testing; identifying failing trigger rate memory dies; and applying the generated ROBP lookup table to enable the failing trigger rate memory dies to pass screening.
Example 13. The system of any one of Examples 1-12, wherein determining the CoV shift comprises: measuring bit error counts for level 7 of a plurality of levels; and updating the ROBP lookup table based on the measured bit error counts for level 7.
Example 14. The system of any one of Examples 1-13, wherein determining the CoV shift comprises: measuring a valley center for level 7 of a plurality of levels; comparing the measured valley center to an original read level; and updating the ROBP lookup table based on a shift between the measured valley center at the plurality of levels and the original read level.
Example 15. The system of any one of Examples 1-14, wherein the memory device comprises a TLC NAND flash memory device.
Example 16. The system of any one of Examples 1-15, wherein the memory device comprises a three-dimensional (3D) NAND device.
Example 17. At least one non-transitory machine-readable storage medium comprising instructions that, when executed by a processing device, cause the processing device to perform operations comprising: determining a CoV shift for an individual memory die; generating a read offset by ROBP lookup table individually associated with the individual memory die based on the determined CoV shift, the ROBP lookup table including read level offset values for different WLG and PEC counts; and applying the ROBP lookup table to adjust read levels for the individual memory die during memory operations to compensate for threshold voltage degradation.
Example 18. A method comprising: determining a CoV shift for an individual memory die; generating a read offset by ROBP lookup table individually associated with the individual memory die based on the determined CoV shift, the ROBP lookup table including read level offset values for different WLG and PEC counts; and applying the ROBP lookup table to adjust read levels for the individual memory die during memory operations to compensate for threshold voltage degradation.
Example 19. The method of Example 18, comprising: measuring read level variations during system background scan operations at predetermined PEC intervals.
Example 20. The method of Example 19, wherein the predetermined PEC intervals comprise at least one of 3,000 cycles, 7,000 cycles, or 10,000 cycles.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

“Read disturb” refers to a phenomenon where repeated read operations on a specific WL in a NAND flash memory block cause unintended changes in the threshold voltages of adjacent cells on unselected WLs within the same block. This effect can potentially lead to data corruption in neighboring cells if left unmanaged, necessitating periodic data refresh or block relocation (folding) operations to maintain data integrity in NAND-based storage devices.

“Slow charge loss (SCL)” refers to charge retention loss or data retention loss that occurs in flash memory cells over time. SCL refers to the gradual leakage of electrical charge from the floating gate of a NAND cell, which can lead to data corruption or loss if left unchecked. This SCL is a natural aging process in flash memory and becomes more pronounced as the memory cells undergo more program/erase cycles and as the manufacturing process shrinks to smaller geometries. The rate of charge loss can be affected by factors such as temperature, the quality of the insulating oxide layer, and the overall design of the memory cell.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device; and
a processing device, operatively coupled to the memory device, configured to perform operations comprising:
determining a center of valley (CoV) shift for an individual memory die;
generating a read offset by program-erase count (ROBP) lookup table individually associated with the individual memory die based on the determined CoV shift, the ROBP lookup table including read level offset values for different word line groups and program-erase count (PEC) counts; and
applying the ROBP lookup table to adjust read levels for the individual memory die during memory operations to compensate for threshold voltage degradation.

2. The system of claim 1, the operations comprising:
measuring read level variations during system background scan operations at predetermined PEC intervals.

3. The operations of claim 2, wherein the predetermined PEC intervals comprise at least one of 3,000 cycles, 7,000 cycles, or 10,000 cycles.

4. The system of claim 1, wherein the ROBP lookup table comprises read level offset values for at least fifteen word line groups.

5. The system of claim 4, wherein the ROBP lookup table comprises read level offset values for at least seven read levels.

6. The system of claim 5, wherein the ROBP lookup table comprises read level offset values for at least four different PEC ranges.

7. The system of claim 6, wherein the PEC ranges comprise 0-999 cycles, 1000-2999 cycles, 3000-6999 cycles, and 7000+ cycles.

8. The system of claim 1, the operations comprising:
measuring valley shifts between adjacent threshold voltage distributions of a specific read level.

9. The system of claim 1, the operations comprising:
accessing the ROBP table generated during manufacture of the individual memory die, the ROBP table generated during manufacture by performing testing operations comprising:
selecting a sacrificial block during wafer-level probe testing of the individual memory die;
applying fast cycling to the sacrificial block; and
measuring slow charge loss (SCL) behavior of the sacrificial block.

10. The system of claim 9, the testing operations comprising:
determining the CoV shift based on the measured SCL behavior to generate the ROBP lookup table before the individual memory die is used in system operations.

11. The system of claim 10, the testing operations comprising:
repeating the testing operations for each memory die during the wafer-level probe testing;
measuring threshold voltage distributions for multiple read levels in the sacrificial block of each respective memory die; and
calculating read level offset values based on the measured threshold voltage distributions.

12. The system of claim 11, the testing operations comprising:
screening the individual memory die using the generated ROBP lookup table during probe testing;
identifying failing trigger rate memory dies; and
applying the generated ROBP lookup table to enable the failing trigger rate memory dies to pass screening.

13. The system of claim 1, wherein determining the CoV shift comprises:
measuring bit error counts for level 7 of a plurality of levels; and
updating the ROBP lookup table based on the measured bit error counts for level 7.

14. The system of claim 1, wherein determining the CoV shift comprises:
measuring a valley center for level 7 of a plurality of levels;
comparing the measured valley center to an original read level; and
updating the ROBP lookup table based on a shift between the measured valley center at the plurality of levels and the original read level.

15. The system of claim 1, wherein the memory device comprises a tri-level cell (TLC) NAND flash memory device.

16. The system of claim 1, wherein the memory device comprises a three-dimensional (3D) NAND device.

17. At least one non-transitory machine-readable storage medium comprising instructions that, when executed by a processing device, cause the processing device to perform operations comprising:
determining a center of valley (CoV) shift for an individual memory die;
generating a read offset by program-erase count (ROBP) lookup table individually associated with the individual memory die based on the determined CoV shift, the ROBP lookup table including read level offset values for different word line groups and program-erase count (PEC) counts; and
applying the ROBP lookup table to adjust read levels for the individual memory die during memory operations to compensate for threshold voltage degradation.

18. A method comprising:
determining a center of valley (CoV) shift for an individual memory die;
generating a read offset by program-erase count (ROBP) lookup table individually associated with the individual memory die based on the determined CoV shift, the ROBP lookup table including read level offset values for different word line groups and program-erase count (PEC) counts; and
applying the ROBP lookup table to adjust read levels for the individual memory die during memory operations to compensate for threshold voltage degradation.

19. The method of claim 18, comprising:
measuring read level variations during system background scan operations at predetermined PEC intervals.

20. The method of claim 19, wherein the predetermined PEC intervals comprise at least one of 3,000 cycles, 7,000 cycles, or 10,000 cycles.
